(19) United States
(12) Patent Application Publication
(10) Pub. No.: US 2020/0303247 A1
(43) Pub. Date: Sep. 24, 2020

(54) SEMICONDUCTOR STRUCTURES WITH A PROTECTIVE LINER AND METHODS OF FORMING THE SAME

(71) Applicant: GLOBALFOUNDRIES INC., Grand Cayman (KY)

(72) Inventors: JIEHUI SHU, Clifton Park, NY (US); HUI ZANG, Guilderland, NY (US); SCOTT HOWARD BEASOR, Greenwich, NY (US); DALI SHAO, Mechanicville, NY (US)

(21) Appl. No.: 16/355,853

(22) Filed: Mar. 18, 2019

(51) Int. Cl. H01L 21/768; H01L 29/417

(52) U.S. Cl. CPC H01L 21/76831; H01L 29/41791; H01L 29/41775; H01L 21/76832

(57) ABSTRACT

The present disclosure generally relates to semiconductor device fabrication and integrated circuits. More particularly, the present disclosure relates to methods of forming a protective liner in transistor devices for protecting one or more gate spacers having a low-K dielectric material. The present disclosure further provides a semiconductor structure including a gate structure having a gate spacer, a trench having upper and lower sidewall portions adjacent to the gate spacer, the trench having a conductive structure over a device element and an adjoining insulative structure over an electrical isolation region, a dielectric liner disposed on the lower sidewall portion of the trench, and a protective liner disposed on the upper sidewall portion of the trench and within the insulative structure.

### FIELD OF THE INVENTION

The present disclosure generally relates to semiconductor device fabrication and integrated circuits. More particularly, the present disclosure relates to methods of forming a protective liner in transistor devices for protecting one or more gate spacers having a low-K dielectric material. The present disclosure also relates to a semiconductor structure with a protective liner formed by the methods disclosed herein.

### BACKGROUND

As the number of devices per chip increases, both inter and intra device dimensions in integrated circuit (IC) design need to decrease. The semiconductor industry's drive for higher density, higher performance, lower-cost devices and the implementation of nanometer-scale process nodes have resulted in the development of various transistor device architectures, such as three-dimensional (3D) fin-shaped field effect transistors (FinFETs), and planar transistor devices built on bulk substrates or substrates with a buried insulator layer (i.e., semiconductor-on-insulator device).

In conventional transistor technologies, device architectures typically include a substrate, an active region, and a gate electrode. The active region may contain electrical input and output contacts and functions as a channel for current flow. The gate electrode is surrounded by a pair of gate spacers, which act as electrical isolation layers to prevent an electrical short between the gate electrode and an adjacent electrical wiring or electrical contact. Low-K dielectric materials have become a preferred material choice in the construction of the gate spacers due to their insulating properties. However, low-K dielectric materials are very susceptible to damages during semiconductor fabrication processes, such as downstream etching processes. Consequently, gate spacers having low-K dielectric materials often end up with numerous defects, such as partial or complete erosion of spacer material, which can cause electrical shorts between the tip of the gate electrode and its adjacent electrical contacts, thereby increasing yield defects in the fabricated semiconductor device.

One possible approach to address the issue of defects is to increase the overall height of the gate structure by adding a capping layer over the gate electrode to act as an insulator to prevent electrical shorts. However, an increased gate height can create other problems during the fabrication processes, such as a weaker structural support of the heightened gate structure. Additionally, as gate-to-gate pitch scales downwards, the formation of trenches between each gate structure and the adjacent electrical connections becomes increasingly challenging with respect to process margin limitations. For example, due to the small size of the gate-to-gate pitch and the increased gate height, conventional patterning and etching processes may cause incomplete removal of material during the formation of the trenches between each gate structure. In addition, conventional metallization processes used to form electrical contacts may also cause incomplete filling of metallization materials in the trenches between each gate structure due to the smaller device dimensions.

Therefore, there is a need to provide methods of forming a semiconductor structure that can overcome, or at least ameliorate, one or more of the disadvantages as described above.

### SUMMARY

In one aspect of the present disclosure, there is provided a semiconductor structure including a gate structure having a gate spacer, a trench having upper and lower sidewall portions adjacent to the gate spacer, the trench having a conductive structure over a device element and an adjoining insulative structure over an electrical isolation region, a dielectric liner disposed on the lower sidewall portion of the trench, and a protective liner disposed on the upper sidewall portion of the trench and within the insulative structure.

In another aspect of the present disclosure, there is provided a semiconductor structure including a gate structure having a gate spacer, a trench having upper and lower sidewall portions adjacent to the gate spacer, the trench having a conductive structure over a device element, a dielectric liner disposed on the lower sidewall portion of the trench, a protective liner disposed on the upper sidewall portion of the trench, and a conductive material within the conductive structure of the trench.

In yet another aspect of the present disclosure, there is provided a method of forming a structure in a semiconductor device by forming a gate structure having a gate spacer, and a trench having upper and lower sidewall portions adjacent to the gate spacer of the gate structure, where the trench has a conductive region and an adjoining insulative region, forming a dielectric liner on the lower sidewall portion of the trench, forming a protective liner on the upper sidewall portion of the trench, and forming a contact opening in the conductive region.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of well-known features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1 is a plan view of a set of device elements for forming a structure in a semiconductor device in accordance with embodiments of the present disclosure.

FIGS. 2A, 2B, and 2C are cross-sectional views taken along lines A-A′, B-B′, and C-C′ as indicated in FIG. 1, respectively, of the set of device elements for forming a structure in a semiconductor device in accordance with embodiments of the present disclosure.

FIGS. 3A-14B are schematic cross-sectional views at various stages of forming a structure in a semiconductor device in accordance with embodiments of the present disclosure.

### DETAILED DESCRIPTION

Various illustrative embodiments of the present disclosure are described below. The embodiments disclosed herein are exemplary and not intended to be exhaustive or limiting to the present disclosure.

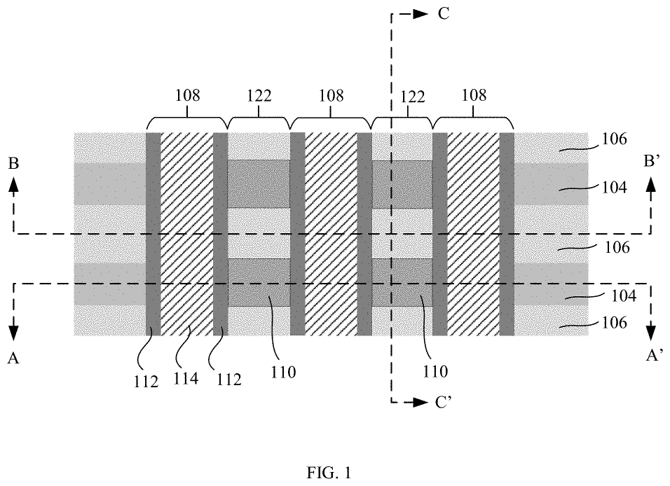

Referring to FIG. 1, a plan view of a set of device elements for forming a semiconductor structure in accordance with the present disclosure is shown. The device elements may include a substrate (not shown in FIG. 1), at least one active region 104 (e.g., a fin) formed on the substrate, at least one gate structure 108 laterally disposed above the active region 104, and a trench 122 adjacent to the gate structure 108 and extends laterally across the active region 104. The device elements may further include at least one source/drain region 110 formed in the active region 104 and adjacent to the gate structure 108. An electrical isolation region 106 may be disposed over the substrate. In one embodiment, the trench 122 is above the source/drain region 110 and the electrical isolation region 106. The device elements shown in FIG. 1 may be formed by conventional semiconductor fabrication processes.

While the active region 104 is represented as a fin in the accompanying drawings, it should be noted that the fin is used only as a non-limiting example of the active region 104, and other active regions (e.g., a doped layer on a top surface of a bulk semiconductor substrate or a semiconductor-on-insulator layer) may be used as well. It should also be understood that the present disclosure can be applied to any type of transistor device architecture, such as a three-dimensional device architecture (e.g., FinFETs), or a planar device architecture (e.g., complementary metal oxide semiconductor (CMOS) devices, semiconductor-on-insulator (SOI) devices, etc.).

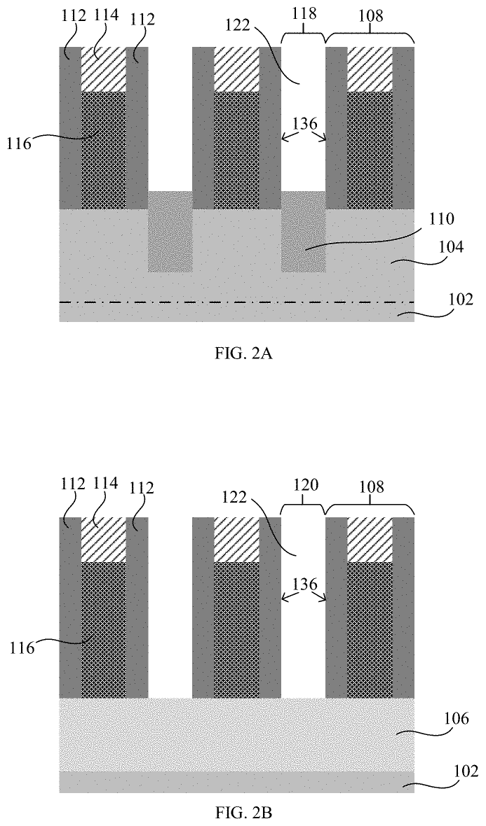

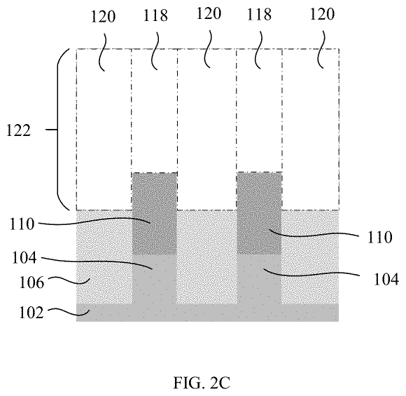

FIGS. 2A, 2B, and 2C depict cross-sectional views (taken along line A-A′, B-B′, C-C′, respectively) of the set of device elements in FIG. 1. Referring to FIGS. 2A and 2B, the gate structure 108 may include a gate cap 114 disposed on a dummy gate electrode 116, and one or more gate spacers 112 disposed on adjacent sides of the dummy gate electrode 116. The trench 122 has sidewalls 136 that are adjacent to the gate spacer 112 of the gate structure 108.

The gate cap 114 may include a nitride compound, such as silicon nitride. The dummy gate electrode 116 may include amorphous silicon. The gate spacer 112 may include a low-K dielectric material. The term “low-K” as used herein refers to a material having a dielectric constant (i.e., K-value) that is lower than 7. Examples of low-K dielectric materials may include, but not limited to, silicon dioxide (SiO₂), silicon oxide materials enriched or doped with atomic elements selected from the group consisting of carbon, boron, hydrogen and nitrogen (e.g., SiOCN, SiBCN), silicon oxynitride (SiON), SiGe oxide, germanium oxide, silicon oxycarbide, SiCOH dielectrics, or any combination of these materials. The gate spacer 112 may have a dielectric constant in the range of about 1 to about 5. In particular, the gate spacer 112 has a dielectric constant in the range of about 1 to about 3.5, and preferably in the range of about 1 to about 3.

The substrate 102 may be made of any suitable semiconductor material, such as silicon (Si), germanium (Ge), silicon germanium (SiGe), silicon/carbon, other II-VI or III-V semiconductor compounds and the like. The substrate 102 may also include an organic semiconductor or a layered semiconductor, such as Si/SiGe, a silicon-on-insulator or a SiGe-on-insulator. In one embodiment, the substrate 102 is preferably silicon.

As shown in FIG. 2A, the active region 104 is formed on the substrate 102. The active region 104 may be made of any suitable semiconductor material, such as silicon, germanium, or silicon germanium. In one embodiment, the active region 104 includes silicon. The source/drain region 110 may be formed by epitaxial growth of a semiconductor material with in-situ doping.

As shown in FIG. 2B, the electrical isolation region 106 is formed on the substrate 102. The electrical isolation region 106 serves to isolate active device elements or circuitry components of an integrated circuit from one another and prevent electrical shorts. The electrical isolation region 106 may include any suitable dielectric material, such as silicon dioxide or silicon nitride. The electrical isolation region 106 can be a shallow trench isolation region or a deep trench isolation region.

Referring to FIG. 2C, the trench 122 includes a conductive region 118 and an adjoining insulative region 120. The conductive region 118 of the trench 122 is disposed above the source/drain region 110 and the insulative region 120 of the trench 122 is disposed above the electrical isolation region 106.

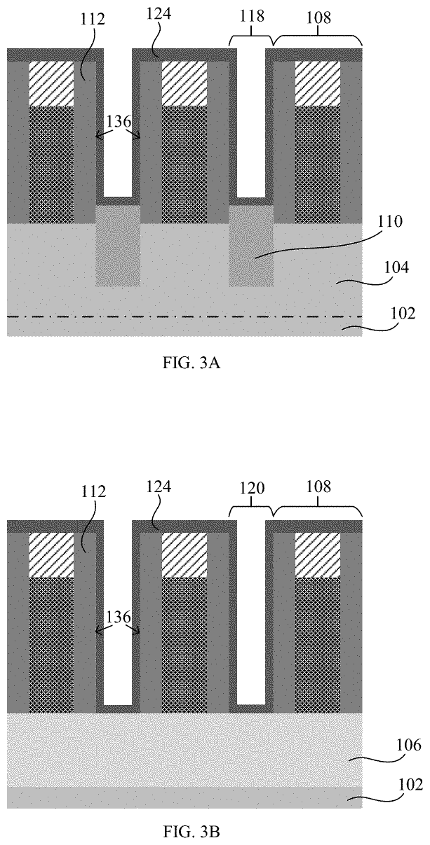

Referring to FIGS. 3A and 3B (FIG. 3A continues from FIG. 2A, and FIG. 3B continues from FIG. 2B), a dielectric liner 124 is formed on the sidewalls 136 of the trench 122. For example, the dielectric liner 124 is formed in the conductive region 118 and the insulative region 120. The dielectric liner 124 may function as an etch stop liner during subsequent fabrication stages. The dielectric liner 124 may be formed by conventional deposition processes. Exemplary techniques for the deposition process include, but not limited to, chemical vapor deposition (CVD), physical vapor deposition (PVD), sputtering, or spin-coating. The dielectric liner 124 may include a dielectric material such as silicon nitride, silicon carbonitride (SiCN), silicon oxide doped/enriched with oxygen and carbon (SiOCN), silicon oxynitride (SiON), silicon carbide (SiC), or silicon oxycarbide (SiOC). In one embodiment, the dielectric liner 124 covers the gate spacer 112, the source/drain region 110 and the electrical isolation region 106. In another embodiment, the dielectric liner 124 has a thickness in the range of about 4 nm to about 8 nm.

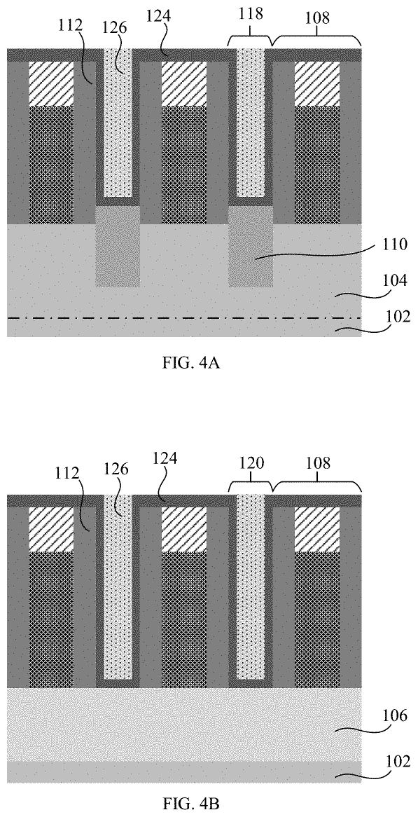

FIGS. 4A and 4B (FIG. 4A continues from FIG. 3A, and FIG. 4B continues from FIG. 3B) illustrate examples for filling the trench with a first dielectric filler material 126. The filling of the trench with the first dielectric filler material 126 may be performed by conventional deposition processes, such as CVD or spin-coating. For example, the first dielectric filler material 126 is filled by performing spin-coating and annealing thereafter. A planarization process (e.g., chemical mechanical planarization (CMP)) may be performed thereafter to ensure that the first dielectric filler material 126 is planar with the gate structure 108.

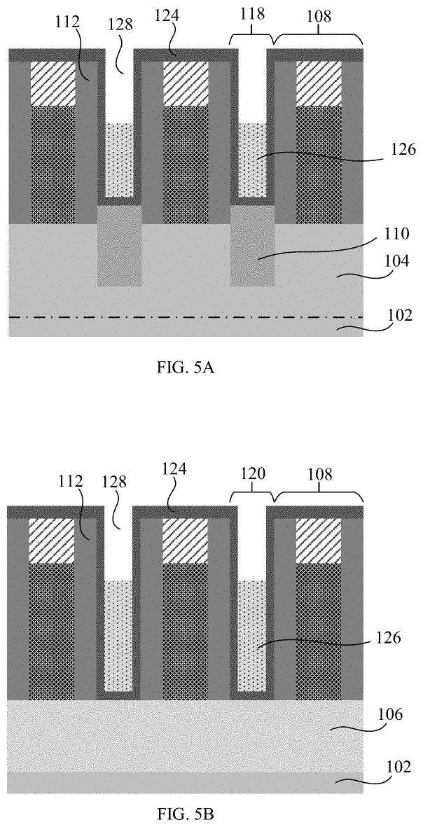

FIGS. 5A and 5B (FIG. 5A continues from FIG. 4A, and FIG. 5B continues from FIG. 4B) illustrate examples for forming a recess 128 within the trench. In particular, the recess 128 is formed in the conductive and insulative regions (118 and 120, respectively). In one embodiment, the recess 128 is formed above the first dielectric filler material 126. The recess 128 may be formed by performing wet etch processes, or dry etch processes. In another embodiment, the recess 128 is formed by performing a wet etch process on the first dielectric filler material 126.

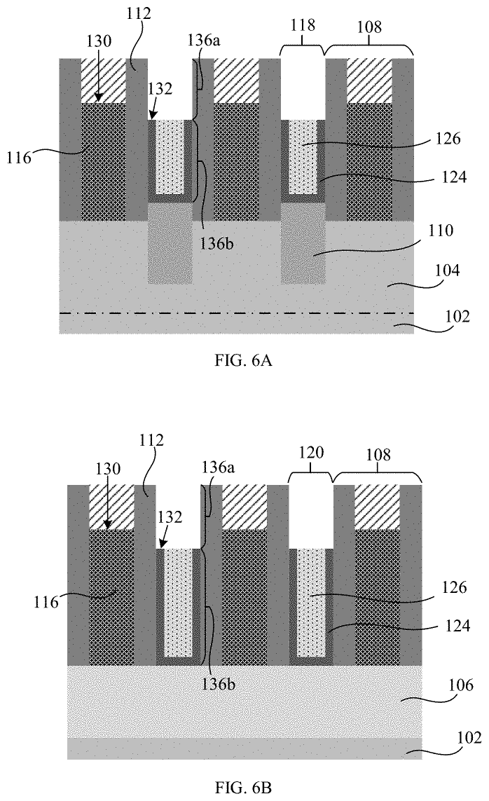

FIGS. 6A and 6B (FIG. 6A continues from FIG. 5A, and FIG. 6B continues from FIG. 5B) illustrate examples for removing a portion of the dielectric liner 124. The removal of the dielectric liner 124 may be performed with isotropic etching and exposes an upper portion 136a of the trench sidewalls in the conductive and insulative regions (118 and 120, respectively). The isotropic etching may be controlled by a predetermined time. In one embodiment, the removal step forms a top edge 132 of the dielectric liner 124, as shown in FIGS. 6A and 6B. In another embodiment, the etching process stops when the top edge 132 of the dielectric liner 124 is proximally below a top surface 130 of the dummy gate electrode 116. The isotropic etching also reveals a top surface of the gate structure 108, as shown in FIGS. 6A and 6B. A lower portion 136b of the trench sidewalls in the conductive and insulative regions (118 and 120, respectively) remains covered by the dielectric liner 124 after the removal.

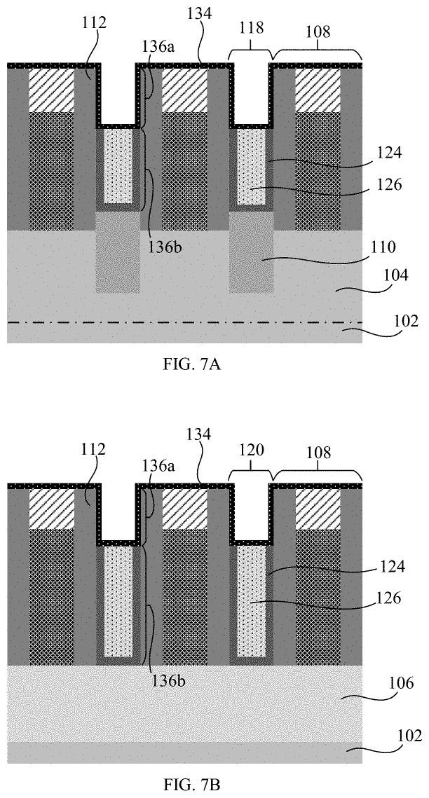

FIGS. 7A and 7B (FIG. 7A continues from FIG. 6A, and FIG. 7B continues from FIG. 6B) illustrate examples for forming a protective liner 134, including on the sidewalls of the trench above the dielectric liner 124, in accordance with embodiments of the present disclosure. The protective liner 134 may be formed by any conventional deposition process. However, a highly conformal deposition process is preferred for depositing the protective liner 134; for example, atomic layer deposition (ALD) process or highly-controlled CVD process. Advantageously, the conformal deposition of the protective liner 134 is found to enable the trench to be completely filled during subsequent fabrication stages, avoid material “pinch-off” at the trench opening, and prevent the formation of voids or “air pockets”.

The protective liner 134 is deposited on the gate structure 108, the dielectric liner 124 and the first dielectric filler material 126. In particular, the protective liner 134 is formed on the exposed upper portion 136a of the trench sidewalls. In one embodiment, the protective liner 134 has a thickness in the range of about 1 nm to about 4 nm. The protective liner 134 is dielectric oxide-containing compound or nitride-containing compound, which may be selected from the group consisting of hafnium oxide, titanium oxide, aluminum oxide, aluminum nitride, and titanium nitride.

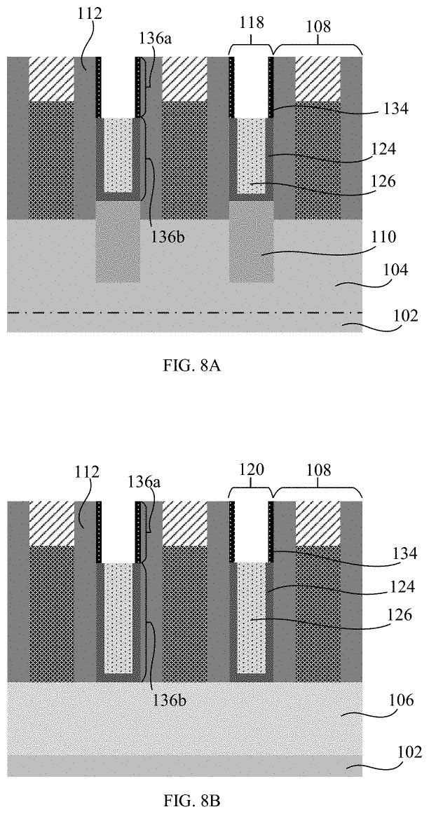

FIGS. 8A and 8B are cross-sectional views depicting successive processing stages of the semiconductor structure, as shown in FIGS. 7A and 7B, in accordance with the present disclosure. An etching process is performed on the protective liner 134 to expose the gate structure 108 and the first dielectric filler material 126. Accordingly, the portion of the protective liner 134 disposed on the upper portions 136a of the trench sidewalls remains after the etching. In one embodiment, the etching process performed on the protective liner 134 is preferably anisotropic etching.

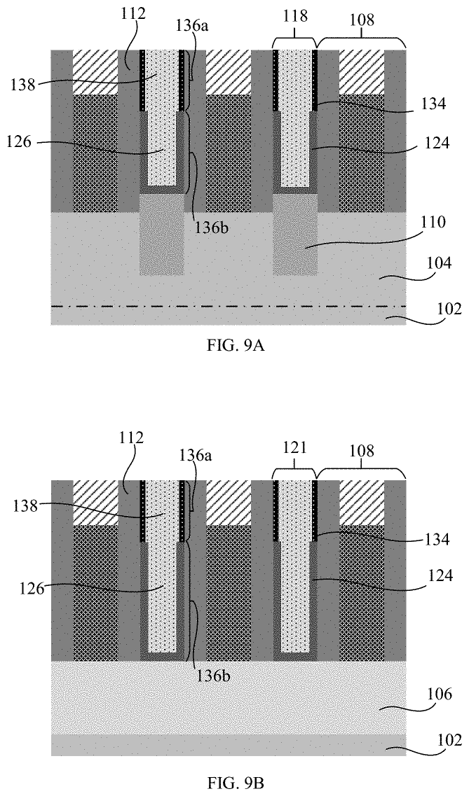

FIGS. 9A and 9B (FIG. 9A continues from FIG. 8A, and FIG. 9B continues from FIG. 8B) illustrate examples for filling the recess with a second dielectric filler material 138. While any conventional deposition processes may be used to fill the recess, it is preferable to use a high plasma deposition (HDP) process to fill the recess. The second dielectric filler material 138 is formed on the first dielectric filler material 126. A planarization process may be performed after the filling. As shown in FIG. 9B, the filling of the recess forms an insulative structure 121 in the insulative region of the trench.

The first and second dielectric filler materials (126 and 138, respectively) may include an oxide material, such as silicon dioxide, a polysilazane-based oxide compound (e.g., Tonen Silazene (TOSZ)), SiON, tetraethyl orthosilicate (TEOS), or silicon-rich silicon oxide. The first and the second filler materials (126 and 138, respectively) may be of the same or different compound. However, it is preferable for the second filler material 138 to be a compound having a higher molecular packing density than the first filler material 126.

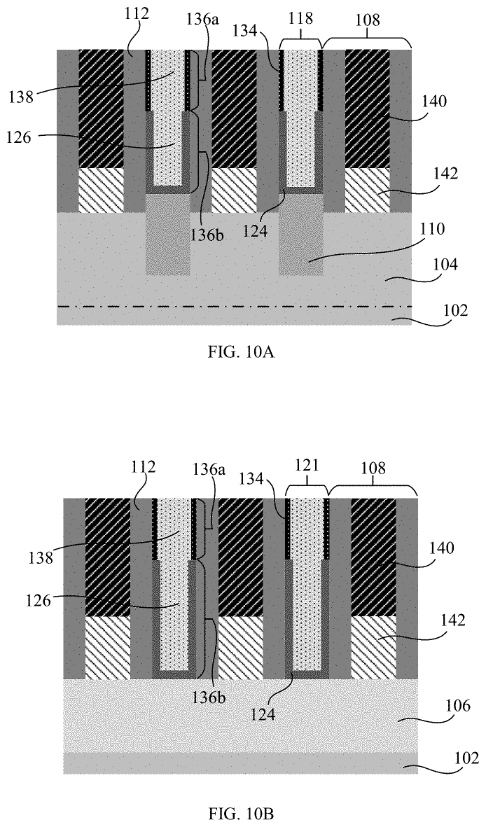

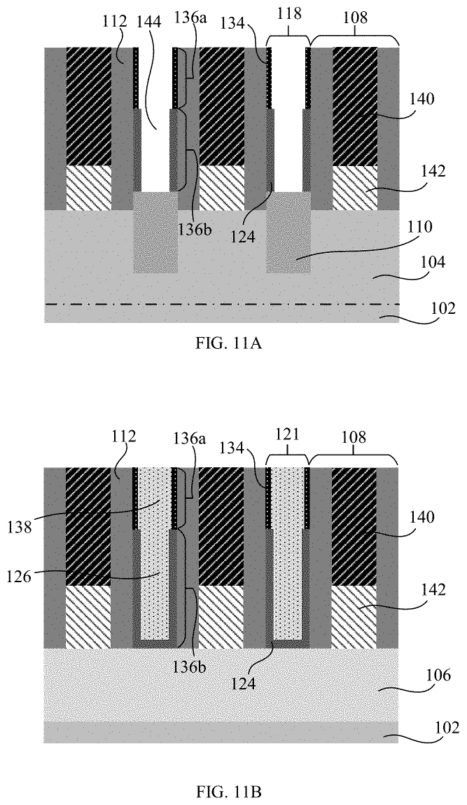

Referring to FIGS. 10A and 10B (FIG. 10A continues from FIG. 9A, and FIG. 10B continues from FIG. 9B), a replacement gate process (RMG) process is performed on the gate structure 108. It should be understood that the RMG process is described at this point in the sequence as an example. The RMG process will be apparent to those of ordinary skill in the art without departing from the scope and spirit of this disclosure. As shown in FIGS. 10A and 10B, the replaced gate structure 108 includes a gate contact 140 formed on a gate stack 142. The gate contact 140 may include an electrically conductive metal, such as tungsten. The gate stack 142 is formed on the active region 104 and may include a high-K dielectric material, such as hafnium silicate, hafnium oxide, zirconium silicate, zirconium oxide, silicon dioxide, titanium nitride, or any combination thereof. In alternative embodiments (not shown), a gate cap is formed to cover the gate contact 140.

Referring to FIGS. 11A and 11B (FIG. 11A continues from FIG. 10A, and FIG. 11B continues from FIG. 10B), a contact opening 144 is formed in the conductive region 118. The contact opening 144 may be formed by performing any suitable etching process, such as a dry etch process or reactive ion etching (ME), and with the use of a mask. The etching process removes the first and second dielectric filler materials (126 and 138, respectively) from the conductive region 118. During the formation of the contact opening 144, the gate spacer 112 is covered by the dielectric liner 124 and the protective liner 134. The protective liner 134, as a dielectric compound described above, is capable of resisting the etching process. Advantageously, the presence of the protective liner 134 on the gate spacer 112 is found to prevent loss of material (e.g., by erosion) and maintain the thickness of the gate spacer 112 during the etching process.

The formation of the contact opening 144 also exposes the source/drain region 110, as shown in FIG. 11A. For example, the etching process is initially stopped by the dielectric liner 124, which acts as the etch stop layer covering the source/drain region 110, and then continued with an over etch to remove the portion that covered the source/drain region 110.

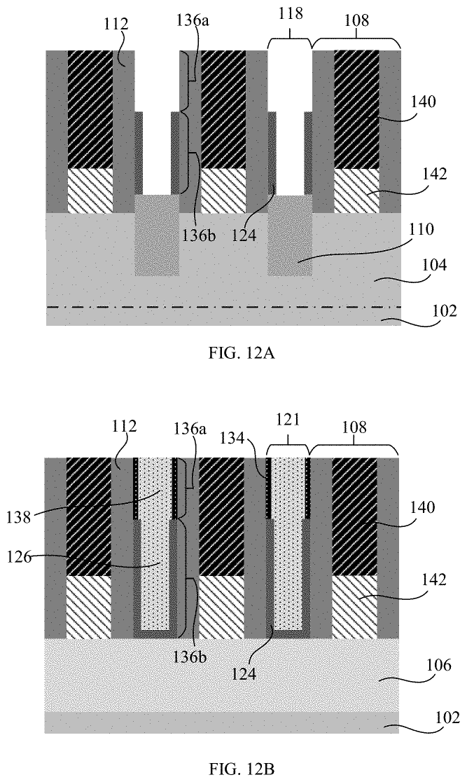

Referring to FIGS. 12A and 12B (FIG. 12A continues from FIG. 11A, and FIG. 12B continues from FIG. 11B), a portion of the protective liner 134 is removed from the conductive region 118. The removal of the protective liner 134 reveals the upper portion 136a of the trench sidewalls within the conductive region 118. The protective liner 134 may be selectively removed by a wet etch or a dry etch process, without the use of a mask.

Advantageously, removing the protective liner 134 from the conductive region 118 is found to reduce the capacitance in the conductive region 118. In alternative embodiments (not shown), the protective liner 134 is permitted to remain in the conductive region 118.

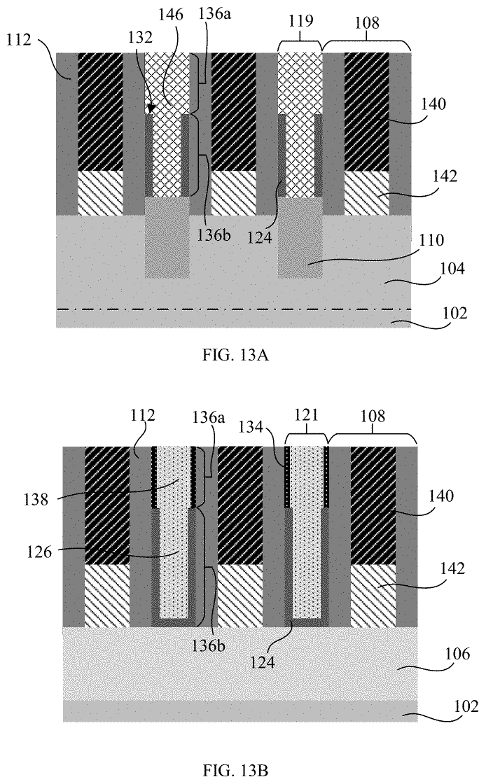

Referring to FIGS. 13A and 13B (FIG. 13A continues from FIG. 12A, and FIG. 13B continues from FIG. 12B), the contact opening is filled with a conductive material 146 to form a conductive structure 119. The conductive material 146 may function as an electrical contact or interconnect layer to connect the source/drain region 110 with other circuitry components integrated into the device. In one embodiment, the conductive material 146 is disposed on the top edge 132 of the dielectric liner 124 and the upper portion 136a of the trench sidewalls. Embodiments for the conductive material 146 may include, but not limited to, copper, cobalt, tungsten, or ruthenium. The conductive material 146 may be formed by conventional deposition processes, such as PVD, CVD or electrochemical plating (ECP).

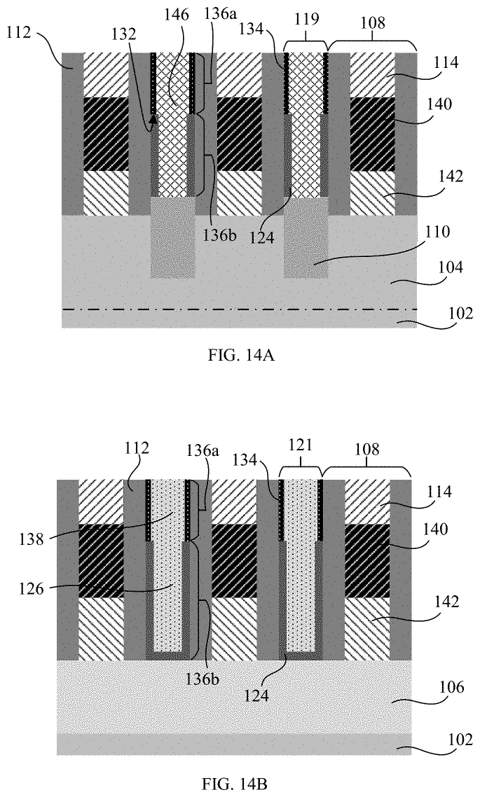

FIGS. 14A and 14B illustrate cross-sectional views of an alternative embodiment of the semiconductor structure formed in accordance with embodiments of the present disclosure. In the alternative embodiment, the gate structure 108 includes a gate cap 114 formed on the gate contact 140. The gate cap 114 is formed during the performance of the RMG process described above. Additionally, the conductive structure 119 includes the protective liner 134 formed above the dielectric liner 124 (i.e., the protective liner 134 is permitted to remain in the conductive region 118 at the fabrication stage shown in FIG. 11A). For example, the protective liner 134 is disposed on the upper portion 136a of the trench sidewalls and above the dielectric liner 124.

Advantageously, as shown in FIGS. 13A and 14A, the gate spacer 112 is maintained after the processing stages described herein and prevents an electrical short between the gate contact 140 and the conductive material 146. More advantageously, the protective liner 134 protects the low-K material in the gate spacer 112 from being eroded away.

As used herein, the term “conductive” refers to the capability of the material, structure, or region to permit the flow of electricity. Conversely, the term “insulative” refers to the capability of the material, structure, or region to prevent the flow of electricity.

Throughout this disclosure, the terms top, upper, upwards, over, and above refer to the direction away from the substrate. Likewise, the terms bottom, lower, downwards, under, and below refer to the direction towards the substrate. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description.

Additionally, the various tasks and processes described herein may be incorporated into a more comprehensive procedure or process having additional functionality not described in detail herein. In particular, various processes in the manufacture of integrated circuits are well-known and so, in the interest of brevity, many conventional processes are only mentioned briefly herein or omitted entirely without providing the well-known process details.

As will be readily apparent to those skilled in the art upon a complete reading of the present application, the methods of forming the semiconductor structure disclosed herein may be employed in replacement metal gate processes for forming FinFET components on a semiconductor device, and may be employed in manufacturing a variety of different integrated circuit products, including, but not limited to, logic products, memory products, planar transistor devices, CMOS devices, SOI devices etc.

1. A semiconductor structure comprising:
a gate structure having a gate spacer;
a trench having upper and lower sidewall portions adjacent to the gate spacer, the trench having a conductive structure over a device element and an adjoining insulative structure over an electrical isolation region;
a dielectric liner disposed on the lower sidewall portion of the trench; and
a protective liner disposed on the upper sidewall portion of the trench and within the insulative structure.

2. The structure of claim 1, further comprising a conductive material within the conductive structure, the conductive material being disposed on a top edge of the dielectric liner and the upper sidewall portion of the trench.

3. The structure of claim 1, wherein the device element is a source/drain region.

4. The structure of claim 1, wherein the protective liner includes a dielectric compound.

5. The structure of claim 4, wherein the dielectric compound is an oxide-containing compound or a nitride-containing compound.

6. The structure of claim 4, wherein the dielectric compound is selected from the group consisting of hafnium oxide, titanium oxide, aluminum oxide, aluminum nitride and titanium nitride.

7. The structure of claim 1, wherein the protective liner has a thickness in the range of 1 nm to 4 nm.

8. The structure of claim 1, wherein the gate spacer has a dielectric constant in the range of 1 to 7.

9. A semiconductor structure comprising:
a gate structure having a gate spacer;
a trench having upper and lower sidewall portions adjacent to the gate spacer, the trench having a conductive structure over a device element;
a dielectric liner disposed on the lower sidewall portion of the trench;
a protective liner disposed on the upper sidewall portion of the trench; and
a conductive material within the conductive structure of the trench.

10. A method of forming a structure in a semiconductor device comprising:
forming a gate structure having a gate spacer, and a trench having upper and lower sidewall portions adjacent to the gate spacer of the gate structure, wherein the trench has a conductive region and an adjoining insulative region;
forming a dielectric liner on the lower sidewall portion of the trench;
forming a protective liner on the upper sidewall portion of the trench; and
forming a contact opening in the conductive region.

11. The method of claim 10, further comprising filling the trench with a first dielectric filler material after forming the dielectric liner.

12. The method of claim 11, further comprising forming a recess within the trench after filling the trench with the first dielectric filler material, wherein the recess is formed above the first dielectric filler material.

13. The method of claim 12, further comprising filling the recess with a second dielectric filler material after forming the protective liner.

14. The method of claim 13, wherein the filling of the recess includes forming an insulative structure in the insulative region of the trench.

15. The method of claim 10, wherein the formation of the protective liner includes conformal deposition of the protective liner followed by anisotropic etching thereof.

16. (canceled)

17. The method of claim 14, further comprising filling the contact opening in the conductive region with a conductive material to form a conductive structure.

18. The method of claim 17, further comprising removing a portion of the protective liner from the conductive region before filling the contact opening with the conductive material.

19. The method of claim 17, wherein the contact opening in the conductive region is formed by removing the first and second dielectric filler materials.

20. The method of claim 10, wherein the gate spacer is covered by the protective liner during formation of the contact opening in the conductive region.

21. The structure of claim 9, wherein the protective liner includes a dielectric compound that is selected from the group consisting of hafnium oxide, titanium oxide, aluminum oxide, aluminum nitride and titanium nitride.
